(19) United States
(12) Patent Application Publication
(10) Pub. No.: US 2016/0050761 A1
(43) Pub. Date: Feb. 18, 2016

(54) SUBSTRATE STRUCTURE AND METHOD OF MANUIFACTURING THE SAME

(71) Applicants: Tzyy-Jang Tseng, Hsinchu (TW); Chien-Nan Wu, Taipei City (TW)

(72) Inventors: Tzyy-Jang Tseng, Hsinchu (TW); Chien-Nan Wu, Taipei City (TW)

(73) Assignee: SUBTRON TECHNOLOGY CO., LTD., Hsinchu County (TW)

(21) Appl. No.: 14/535,301

(22) Filed: Nov. 6, 2014

(30) Foreign Application Priority Data
Aug. 12, 2014 (TW) 103127636

(51) Int. Cl. H05K 3/00; H05K 1/02; H05K 3/04

(52) U.S. Cl. CPC H05K 3/0029; H05K 3/045; H05K 1/0296; H05K 2203/025; H05K 2203/072; H05K 2201/0305

(57) ABSTRACT

A method of manufacturing a substrate structure is provided. An insulation substrate having an upper surface is provided. A portion of the upper surface of the insulation substrate is irradiated by a first laser beam so as to form a first intaglio pattern. The first laser beam is IR laser beam or fiber laser beam. The first intaglio pattern has a modification surface. A first metal layer is formed on the upper surface of the insulation substrate, and covers the upper surface of the insulation layer and the modification surface of the first intaglio pattern, and fills up the first intaglio pattern. A grinding process is performed on the first metal layer so as to expose the upper surface of the insulation substrate and define a first patterned circuit layer. A first upper surface of the first patterned circuit layer is aligned with the upper surface of the insulation substrate.

### CROSS-REFERENCE TO RELATED APPLICATION

This application claims the priority benefit of Taiwan application serial no. 103127636, filed on Aug. 12, 2014. The entirety of the above-mentioned patent application is hereby incorporated by reference herein and made a part of this specification.

### BACKGROUND OF THE INVENTION

1. Field of the Invention

The invention relates to a substrate structure and a method of manufacturing the same, and more particularly to a substrate structure having more preferable thermal conducting effects and a method of manufacturing the same.

2. Description of Related Art

In general, when manufacturing a circuit layer on an insulation substrate, the circuit layer is usually manufactured on an upper surface of the insulation substrate. Therefore, when a heating device is disposed on the circuit layer, the heat generated by the heating device has to pass through the thickness of the circuit layer and the thickness of the insulation substrate to be transmitted to an external environment. Thereby, the thermal resistance in the heat dissipation path of the heating device is larger, and the effect of rapid thermal conduction is not achieved.

To solve this problem, it is conventional to reduce the thickness of the insulation substrate by grinding; alternatively, an embedded circuit layer is manufactured by exposure, lithography and etching, so as to reduce the thickness of the insulation substrate, so that the thermal resistance in the heat dissipation path is effectively reduced. However, such means all increase the manufacturing steps and are time-consuming and not easy for mass production.

### SUMMARY OF THE INVENTION

Accordingly, the present invention is directed to a substrate structure having more preferable thermal conduction effects.

The present invention is further directed to a method of manufacturing the substrate structure for manufacturing the above-mentioned substrate structure.

The present invention provides a method of manufacturing the substrate structure including the following steps. An insulation substrate is provided, wherein the insulation substrate has an upper surface. A portion of the upper surface of the insulation substrate is irradiated by a first laser beam so as to form a first intaglio pattern, wherein the first laser beam is IR laser beam or fiber laser beam, and the first intaglio pattern has a modification surface. A first metal layer is formed on the upper surface of the insulation substrate, wherein the first metal layer covers the upper surface of the insulation layer and the modification surface of the first intaglio pattern and fills up the first intaglio pattern. A grinding process is performed on the first metal layer so as to expose the upper surface of the insulation substrate and to define a first patterned circuit layer, wherein a first upper surface of the first patterned circuit layer is coplanar with the upper surface of the insulation substrate.

The present invention further provides a substrate structure including an insulation substrate and a first patterned circuit layer. The insulation substrate has an upper surface and a first intaglio pattern situated on the upper surface. The first patterned circuit layer is disposed in the first intaglio pattern and fills up the first intaglio pattern, wherein a first surface of the first patterned circuit layer is coplanar with the upper surface of the insulation substrate.

According to an embodiment of the invention, a material of the insulation substrate includes ceramics (such as aluminum oxide, aluminum nitride, silicon carbide or silicon nitride) or glass.

According to an embodiment of the invention, a depth of the first intaglio pattern is from 0.3% to 60% of the thickness of the insulation substrate.

According to an embodiment of the invention, the method of forming the first metal layer on the upper surface of the insulation substrate is an electroless plating process.

According to an embodiment of the invention, a material of the first metal layer includes copper or nickel.

According to an embodiment of the invention, the method of manufacturing the substrate structure further includes the following steps. A solder mask is formed on the first patterned circuit layer after the grinding process is performed on the first metal layer, wherein the solder mask exposes a portion of the first patterned circuit layer. Also, a surface treatment layer is formed on the first patterned circuit layer exposed by the solder mask.

According to an embodiment of the invention, when the insulation substrate is provided, the insulation substrate already has a cavity (may be formed by punching during the manufacture of the insulation substrate), and the upper surface is a 3-D surface.

According to an embodiment of the invention, the insulation substrate further has a lower surface opposite to the upper surface, and the method of manufacturing the substrate structure further includes the following steps. Before the first metal layer is formed on the upper surface of the insulation substrate, a portion of the lower surface of the insulation substrate is irradiated by a second laser beam, so as to form a second intaglio pattern.

According to an embodiment of the invention, the method of manufacturing the substrate structure further includes the following steps. A second metal layer is formed on the lower surface of the insulation substrate after the second intaglio pattern is formed, wherein the second metal layer fills up the second intaglio pattern and forms a second patterned circuit layer, and a second lower surface of the second patterned circuit layer is coplanar with the lower surface of the insulation substrate.

According to an embodiment of the invention, a depth of the first intaglio pattern is from 0.3% to 40% of the thickness of the insulation substrate, and a depth of the second intaglio pattern is from 0.3% to 40% of the thickness of the insulation substrate.

According to an embodiment of the invention, the insulation substrate further has a lower surface opposite from the upper surface and a second intaglio pattern situated on the lower surface.

According to an embodiment of the invention, the substrate structure further includes a second patterned circuit layer disposed in the second intaglio pattern and filling up the second intaglio pattern, wherein a second lower surface of the second patterned circuit layer is coplanar with the lower surface of the insulation substrate.

According to an embodiment of the invention, the insulation substrate further has a cavity, and the upper surface is a 3-D surface.

According to an embodiment of the invention, the substrate structure further includes a solder mask and a surface treatment layer. The solder mask is disposed on the first patterned circuit layer, wherein the solder mask exposes a portion of the first patterned circuit layer. The surface treatment layer is disposed on the first patterned circuit layer exposed by the solder mask.

Based on the above, in the substrate structure of the invention, the intaglio pattern is formed on the insulation substrate via IR laser beam or fiber laser beam, the metal layer is then formed in the intaglio pattern, and the patterned circuit layer is defined via the grinding process. Therefore, compared with conventional methods for forming an embedded circuit by exposure, lithography and etching processes, the manufacturing steps in the method of manufacturing the substrate of the invention is rather simple, which reduces manufacturing time and production cost, and thus is more suitable for mass production. In addition, since the patterned circuit layer of the invention is disposed in the intaglio pattern of the insulation substrate (which means that the patterned circuit layer may be deemed as an embedded circuit), the thickness of a portion of the insulation substrate is reduced. When a heating device is disposed on the patterned circuit layer, the heat generated by the heating device passes through the insulation substrate having a thinner thickness to be transmitted to an external environment. Therefore, the thermal resistance of the heat dissipation path is effectively reduced, and thereby thermal conduction effects of the substrate structure are enhanced.

To make the above features and advantages of the present invention more comprehensible, several embodiments accompanied with drawings are described in detail as follows.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIGS. 1A to 1E are schematic cross-sectional views of a method of manufacturing a substrate structure according to an embodiment of the invention.

FIG. 2A is a schematic cross-sectional view of a substrate structure according to an embodiment of the invention.

FIGS. 2B and 2C are schematic cross-sectional views of partial steps in a method of manufacturing the substrate structure of FIG. 2A.

FIG. 3 is a schematic cross-sectional view of partial steps in a method of manufacturing a substrate structure according to an embodiment of the invention.

FIG. 4 is a schematic cross-sectional view of a substrate structure according to another embodiment of the invention.

FIG. 5 is a schematic cross-sectional view of a substrate structure according to yet another embodiment of the invention.

### DESCRIPTION OF EMBODIMENTS

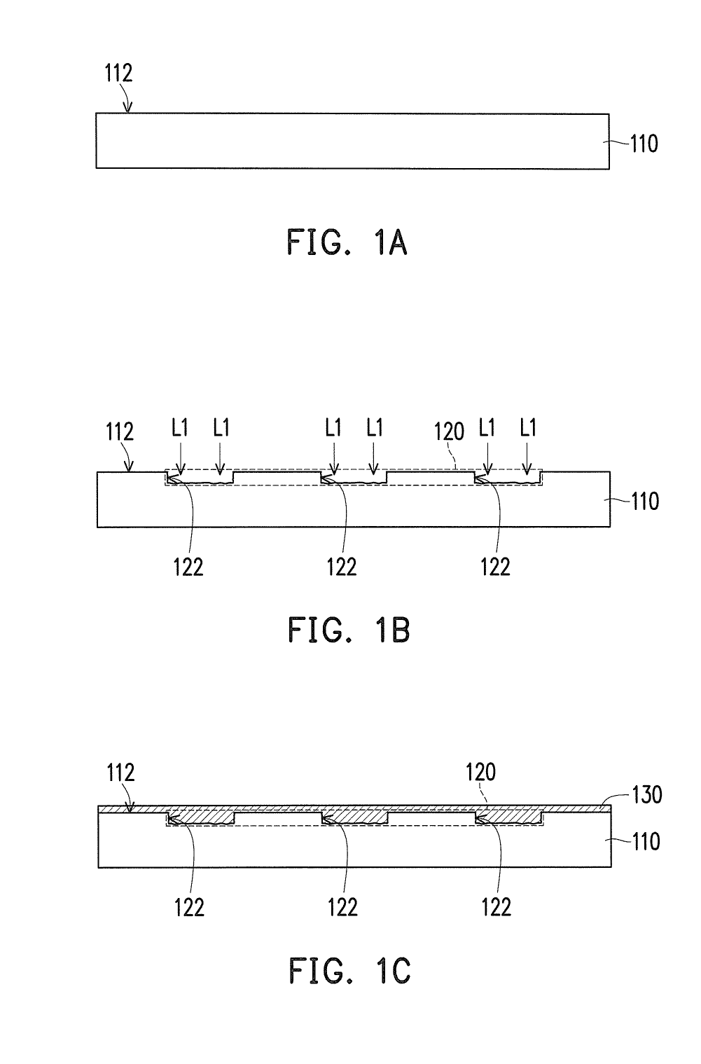

FIGS. 1A to 1E are schematic cross-sectional views of a method of manufacturing a substrate structure according to an embodiment of the invention. Referring to FIG. 1E, in this embodiment, a substrate structure 100 includes an insulation substrate 110 and a first patterned circuit layer 140. The insulation substrate 110 has an upper surface 112 and a first intaglio pattern 120 situated on the upper surface 112. The first patterned circuit layer 140 is disposed in the first intaglio pattern 120 and fills up the first intaglio pattern 120, wherein a first surface 142 of the first patterned circuit layer 140 is coplanar with the upper surface 112 of the insulation substrate 110. Furthermore, to protect the first patterned circuit layer 140 effectively, the substrate structure 100 of this embodiment may further include a solder mask 150 and a surface treatment layer 160. The solder mask 150 is disposed on the first patterned circuit layer 140 and exposes a portion of the first patterned circuit layer 140, and the surface treatment layer 160 is disposed on the first patterned circuit layer 140 exposed by the solder mask 150.

In the manufacturing process, according to the method of manufacturing the substrate structure of this embodiment, referring to FIG. 1A first, an insulation substrate 110 is provided, wherein the insulation substrate 110 has an upper surface 112, and the upper surface 112 is a flat plane. In this embodiment, a material of the insulation substrate 110 is, for example, ceramics (such as aluminum oxide, aluminum nitride, silicon carbide or silicon nitride) or glass. More preferably, a thermal conductivity of the insulation substrate 110 is from 10 W/m·K to 300 W/m·K, and a thickness of the insulation substrate 110 is from 0.3 mm to 3 mm.

Next, referring to FIG. 1B, a portion of the upper surface 112 of the insulation substrate 110 is irradiated by a first laser beam L1, so as to form a first intaglio pattern 120. More particularly, the first laser beam L1 of this embodiment is specifically infrared (IR) laser beam or fiber laser beam, and the first intaglio pattern 120 has a modification surface 122. Herein, a depth of the first intaglio pattern 120 is more preferably from 0.3% to 60% of the thickness of the insulation substrate 110, and a power of the first laser beam L1 is more preferably from 5 watt to 100 watt.

It needs to be noted that the modification surface 122 described herein is substantially an inner wall of the first intaglio pattern 120, and the modification surface 122 is formed by removing non-metal materials within the insulation substrate 110 via the first laser beam L1. The purpose of forming the modification surface 122 is to enhance the bonding force between a first metal layer 130 (referring to FIG. 1C) and the insulation substrate 110. In addition, the forming of the first intaglio pattern 120 merely removes a thickness of a partial region of the insulation substrate 110, and therefore does not affect the overall structural strength of the insulation substrate 110.

Next, referring to FIG. 1C, a first metal layer 130 is formed on the upper surface 112 of the insulation substrate 110, wherein the first metal layer 130 covers the upper surface 112 of the insulation layer 110 and the modification surface 122 of the first intaglio pattern 120, and fills up the first intaglio pattern 120. To be more specific, the method of forming the first metal layer 130 on the upper surface 112 of the insulation substrate 110 is an electroless plating process, i.e., chemical plating, and a material of the first metal layer 130 is, for example, copper, nickel or other adequate metal materials.

Then, referring to both FIGS. 1C and 1D, a grinding process is performed on the first metal layer 130 so as to expose the upper surface 112 of the insulation substrate 110 and define a first patterned circuit layer 140, wherein a first upper surface 142 of the first patterned circuit layer 140 is substantially coplanar with the upper surface 112 of the insulation substrate 110. In other words, the first patterned circuit layer 140 herein may be deemed an embedded circuit.

It needs to be noted that in addition to defining the first patterned circuit layer 140 situated in the first intaglio pattern 120, the purpose of the grinding process is also to prevent short circuit from occurring in the defined first patterned circuit layer 140. On the other hand, the surface roughness of the first patterned circuit layer 140 may also be reduced, thereby enhancing subsequent packaging quality. Herein, the grinding process is, for example, chemical mechanical polishing (CMP) or Electrochemical Polish (ECP).

Finally, referring to FIG. 1E, to effectively protect the first patterned circuit layer 140 from oxidation reactions, after the grinding process is performed on the first metal layer 130, a solder mask 150 is formed on the first patterned circuit layer 140, wherein the solder mask 150 covers a portion of the first patterned circuit layer 140 and exposes a portion of the first patterned circuit layer 140. Herein, in addition to protecting the first patterned circuit layer 140, the purpose of the solder mask 150 is also to prevent short circuit from occurring in the first patterned circuit layer 140. More preferably, a material of the solder mask 150 is, for example, epoxy, polyimide (PI) or other adequate materials. Next, a surface treatment layer 160 is formed on the first patterned circuit layer 140 exposed by the solder mask 150, so as to effectively protect the first patterned circuit layer 140 from oxidation. More preferably, the surface treatment layer 160 may be formed by sputtering, electroplating or chemical plating, etc., wherein the surface treatment layer 160 is, for example, a gold layer, a silver layer, a tin layer, a bismuth layer, a nickel gold layer, a nickel silver layer, a palladium nickel layer, a nickel palladium gold layer, a palladium copper layer or a tin-bismuth alloy layer. So far, the substrate structure 100 has been manufactured.

The substrate structure 100 of this embodiment is manufacturing by forming the first intaglio pattern 120 on the insulation substrate 110 via IR laser beam or fiber laser beam and then forming the metal layer 130 in the first intaglio pattern 120, and the first patterned circuit layer 140 (may be deemed an embedded circuit) is defined via the grinding process. Therefore, compared with conventional methods for forming an embedded circuit by exposure, lithography and etching processes, the method of manufacturing the substrate 100 in this embodiment has rather simple manufacturing steps, which reduces manufacturing time and production cost, and thus the method is more suitable for mass production than the prior art.

In addition, since the thermal conductivity of the insulation substrate 110 adopted in this embodiment is greater (i.e., from 10 W/m·K to 300 W/m·K), the insulation substrate 110 of this embodiment may be deemed a highly conductive insulation substrate. Furthermore, since the patterned circuit layer 140 of this embodiment is disposed in the first intaglio pattern 120 of the insulation substrate 110, the thickness of the portion of the insulation substrate 110 is reduced, but the overall structural strength of the substrate structure 100 is not affected. Therefore, when a heating device (not shown) is disposed on the first patterned circuit layer 140, heat generated by the heating device passes through the insulation substrate 110 having a thinner thickness (that is, the remaining thickness of the insulation substrate 110 after subtracting the thickness of the first patterned circuit layer 140 from the original thickness of the insulation substrate 110) to be transmitted to an external environment. Therefore, thermal resistance in the heat dissipation path is effectively reduced, which thereby enhances thermal conduction effects of the substrate structure 100.

It should be noted herein that the reference numerals and part of the contents in the previous embodiment are used in the following embodiments, in which identical reference numerals indicate identical or similar components, and repeated description of the same technical contents is omitted. For a detailed description of the omitted parts, reference can be found in the previous embodiment, and no description will be repeated in the following embodiments.

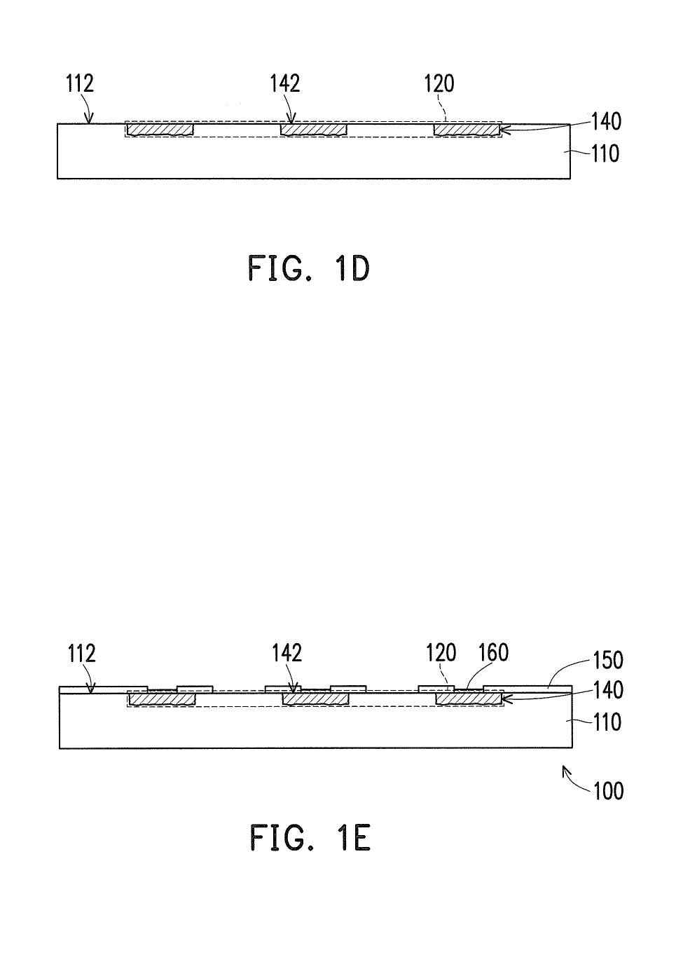

FIG. 2A is a schematic cross-sectional view of a substrate structure according to an embodiment of the invention. Referring to both FIGS. 1E and 2A, a substrate structure 100a of this embodiment is similar to the substrate structure 100 in FIG. 1E, and the primary difference lies in: an insulation substrate 110′ in this embodiment further has a lower surface 114 opposite to the upper surface 112 and a second intaglio pattern 120′ situated on the lower surface 114, wherein a second patterned circuit layer 140′ is disposed in the second intaglio pattern 120′ and fills up the second intaglio pattern 120′. More preferably, a second lower surface 142′ of the second patterned circuit layer 140′ is substantially coplanar with the lower surface 114 of the insulation substrate 110′.

In the manufacturing process, after the step of FIG. 1B and before the step of FIG. 1C, that is, after the first intaglio pattern 120 is formed and before the first metal layer 130 is formed on the upper surface 112 of the insulation substrate 110, referring to FIG. 2B, a portion of the lower surface 114 of the insulation substrate 110′ is irradiated by a second laser beam L2 to form a second intaglio pattern 120′, wherein the second intaglio pattern 120′ has a modification surface 122′. Herein, as shown in FIG. 2B, a depth of the second intaglio pattern 120′ in this embodiment is substantially larger than the depth of the first intaglio pattern 120, but the invention is not limited thereto. More preferably, the depth of the first intaglio pattern 120 is from 0.3% to 40% of the thickness of the insulation substrate 110′, and the depth of the second intaglio pattern 120′ is from 0.3% to 40% of the thickness of the insulation substrate 110′. Next, referring to FIG. 2C, a first metal layer 130 is formed on the upper surface 112 of the insulation substrate 110′, wherein the first metal layer 130 covers the upper surface 112 of the insulation layer 110′. Then, a second metal layer 130′ is formed on the lower surface 114 of the insulation substrate 110′, wherein the second metal layer 130′ covers the lower surface 114 of the insulation layer 110′ and the modification surface 122′ of the second intaglio pattern 120′, and fills up the second intaglio pattern 120′.

It needs to be noted that the step of forming the second metal layer 130′ is performed after the step of forming the first metal layer 130. However, in other embodiments, the step of forming the second metal layer 130′ may also be performed before the step of forming the first metal layer 130; alternatively, the first metal layer 130 and the second metal layer 130′ are formed simultaneously. In other words, if the first metal layer 130 and the second metal layer 130′ are formed simultaneously, the material of the first metal layer 130 and the second metal layer 130′ may be the same; if the first metal layer 130 and the second metal layer 130′ are not formed simultaneously, the materials of the first metal layer 130 and the second metal layer 130′ may be the same or different.

Furthermore, if the first metal layer 130 and the second metal layer 130′ are manufactured simultaneously, i.e., the first metal layer 130 and the second metal layer 130′ are composed of the same material, since the depth of the first intaglio pattern 120 is smaller than the depth of the second intaglio pattern 120′, a blocking layer (such as an adhesive tape) is adhered to the first metal layer 130 when the first metal layer 130 fills up the first intaglio pattern 120 and covers the upper surface 112 of the insulation substrate 110′, and then the process is continued so that the second metal layer 130′ fills up the second intaglio pattern 120′ and covers the lower surface 114 of the insulation substrate 110′. Such a procedure reduces the subsequent manufacturing time for grinding the first metal layer 130. Alternatively, the second metal layer 130′ fills up the second intaglio pattern 120′ and covers the lower surface 114 of the insulation substrate 110′. At this point, the first metal layer 130 has also filled up the first intaglio pattern 120 and covered the upper surface 112 of the insulation substrate 110′. However, such a method requires more time for subsequently grinding the first metal layer 130.

It is worth noting that although the portion of the lower surface 114 of the insulation substrate 110′ is irradiated by the second laser beam L2 to form the second intaglio pattern 120′, in other embodiments, an insulation substrate 110′ having the second intaglio pattern 120′ may also be provided directly. That is, by forming the insulation substrate 110′ having the second intaglio pattern 120′ via punching, the process of manufacturing the second intaglio pattern 120′ is omitted, which effectively reduces the steps of manufacturing the substrate structure 100a and the cost for production.

Next, as in the step of FIG. 1D, a grinding process is performed on the first metal layer 130 and the second metal layer 130′ respectively, so as to expose the upper surface 112 and the lower surface 114 of the insulation substrate 110′, so that the first patterned circuit layer 140 and the second patterned circuit layer 140′ are defined respectively, as shown in FIG. 2A. More specifically, the first upper surface 142 of the first patterned circuit layer 140 is substantially coplanar with the upper surface 112 of the insulation substrate 110′, and the second lower surface 142′ of the second patterned circuit layer 140′ is substantially coplanar with the lower surface 114 of the insulation substrate 110′. Lastly, the step in FIG. 1E is performed, which is to form the solder mask 150 and the surface treatment layer 160. Now the substrate structure 110a has been manufactured.

Since in this embodiment, the embedded first patterned circuit layer 140 and second patterned circuit layer 140′ are disposed respectively on the upper surface 112 and the lower surface 114 of the insulation substrate 110′, the thickness of a portion of the insulation substrate 110′ is effectively reduced. Furthermore, the depth of the second intaglio layer 120′ is greater than the depth of the first intaglio layer 120. Therefore, when the first metal layer 130 and the second metal layer 130′ are formed respectively in the first intaglio layer 120 and the second intaglio layer 120′, thus defining the first patterned circuit layer 140 and the second patterned circuit layer 140′, the second intaglio layer 140′ has more preferable heat dissipation effects than the first patterned circuit layer 140. Therefore, when a heating device (not shown) is disposed on the first patterned circuit layer 140, heat generated by the heating device passes through the insulation substrate 110′ having a thinner thickness (that is, the remaining thickness of the insulation substrate 110′ after subtracting the thickness of the first patterned circuit layer 140 and/or the thickness of the second patterned circuit layer 140′ from the original thickness of the insulation substrate 110′) to be transmitted to an external environment with the high thermal conductivity of the second patterned circuit layer 140′ (i.e., the thermal conductivity of the second patterned circuit layer 140′ is greater than the thermal conductivity of the insulation substrate 110′). Therefore, thermal resistance in the heat dissipation path is effectively reduced, which thereby enhances thermal conduction effects of the substrate structure 100a.

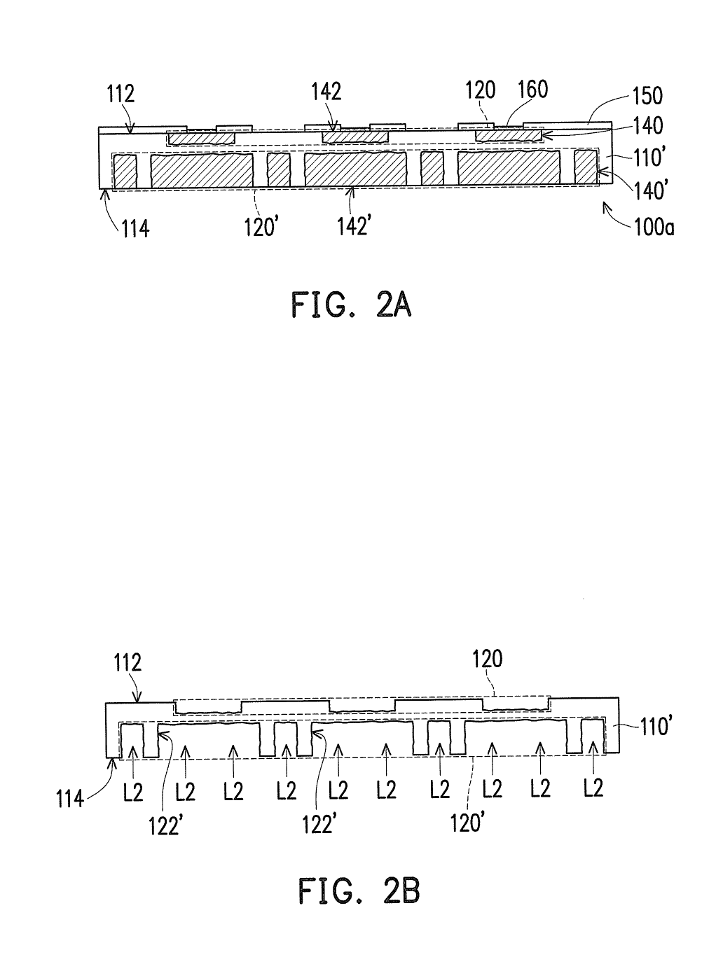

FIG. 3 is a schematic cross-sectional view of partial steps in a method of manufacturing a substrate structure according to an embodiment of the invention. Referring to both FIGS. 1E and 3, a substrate structure 100b of this embodiment is similar to the substrate structure 100 in FIG. 1E, and the substrate structure 100b of this embodiment is a semi-product. More specifically, after the step of FIG. 1E, i.e., after the solder mask 150 and the surface treatment layer 160 are formed, the lower surface 114 opposite from the upper surface 112 of the insulation substrate 110′ may also be irradiated by the second laser beam L2, so as to form the second intaglio pattern 120′. Herein, the purpose of forming the second intaglio pattern 120′ is to reduce the thickness of the insulation substrate 110′. Lastly, the insulation substrate 110′ is cut along a cutting line C, so as to form a plurality of substrate structures 100b′. At this point, a thickness of the sub-substrate structure 110b′ is apparently much smaller than the thickness of the original insulation substrate 110′. Therefore, the sub-substrate structure 100b′ may be deemed an ultra-thin and highly thermal conductive substrate structure.

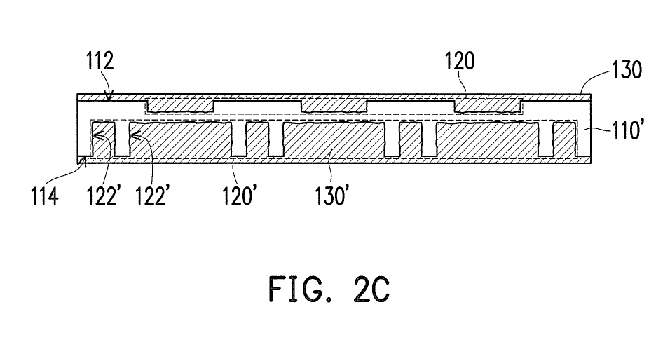

FIG. 4 is a schematic cross-sectional view of a substrate structure according to another embodiment of the invention. Referring to both FIGS. 1E and 4, a substrate structure 100c of this embodiment is similar to the substrate structure 100 in FIG. 1E, and the primary difference lies in: an insulation substrate 110″ in this embodiment further has a cavity 111. Specifically, an upper surface 112″ is a three-dimensional (3-D) surface. As shown in FIG. 4, the upper surface 112″ is composed of a flat plane and an inclined surface surrounding this flat plane. More specifically, the cavity 111 may be formed by being irradiated with the laser beam. At this point, the upper surface 112″ of the insulation substrate 110″ is a 3-D surface. Next, as the step in FIG. 1B, a portion of the upper surface 112″ of the insulation substrate 110″ is irradiated by the first laser beam L1, so as to form the first intaglio pattern 120″. Then, following the steps in FIGS. 1C to 1E, the substrate structure 100c has been manufactured.

Since the upper surface 112″ of the insulation substrate 110″ of this embodiment is a 3-D surface, and the first intaglio pattern 120″ is disposed along the cavity 111, a first patterned circuit layer 140″ defined subsequently may be deemed a 3-D embedded circuit. In addition, the arrangement of the cavity 111 reduces the thickness of a portion of the insulation substrate 110″. Therefore, when a heating device (not shown) is disposed on the first patterned circuit layer 140″, heat generated by the heating device passes through the insulation substrate 110″ having a thinner thickness to be transmitted to an external environment. Thus, thermal resistance of the heat dissipation path is effectively reduced, and thereby thermal conduction effects of the substrate structure 100c are enhanced.

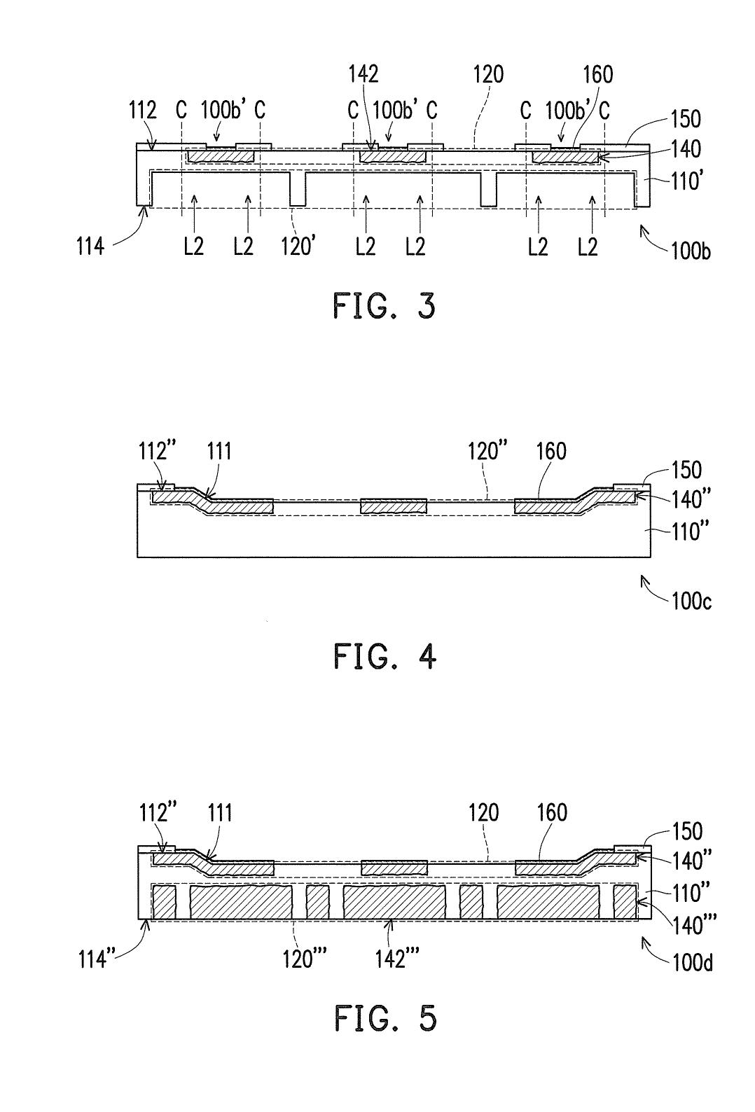

FIG. 5 is a schematic cross-sectional view of a substrate structure according to yet another embodiment of the invention. Referring to both FIGS. 4 and 5, a substrate structure 100d of this embodiment is similar to the substrate structure 100c in FIG. 4, and the primary difference lies in: the insulation substrate 110″ in this embodiment further has a lower surface 114″ opposite from the upper surface 112″ and a second intaglio pattern 120′″ situated on the lower surface 114″, wherein a second patterned circuit layer 140′″ is disposed in the second intaglio pattern 120′″ and fills up the second intaglio pattern 120′″. More preferably, a second lower surface 142′″ of the second patterned circuit layer 140′″ is substantially coplanar with the lower surface 114″ of the insulation substrate 110″. In the manufacturing process, the ways of forming the second intaglio pattern 120′″ and the second patterned circuit layer 140′″ are the same as the manufacturing steps of FIGS. 2B and 2C.

Since in this embodiment, the embedded first patterned circuit layer 140″, the cavity 111 and the second patterned circuit layer 140′″ are disposed respectively on the upper surface 112″ and the lower surface 114″ of the insulation substrate 110″, the thickness of a portion of the insulation substrate 110″ is effectively reduced. Therefore, when a heating device (not shown) is disposed on the first patterned circuit layer 140″, heat generated by the heating device is transmitted to an external environment via the high thermal conductivity of the insulation substrate 110′ having a thinner thickness. Thus, thermal resistance of the heat dissipation path is effectively reduced, and thereby thermal conduction effects of the substrate structure 100d are enhanced.

In the substrate structure of the invention, the intaglio pattern is formed on the insulation substrate via IR laser beam or fiber laser beam, the metal layer is then formed in the intaglio pattern, and the patterned circuit layer is defined via the grinding process. Therefore, compared with conventional methods for forming an embedded circuit by exposure, lithography and etching processes, the manufacturing steps in the method of manufacturing the substrate of the invention is rather simple, which reduces manufacturing time and production cost, and therefore is more suitable for mass production. In addition, since the patterned circuit layer of the invention is disposed in the intaglio pattern of the insulation substrate (which means that the patterned circuit layer may be deemed an embedded circuit), the thickness of a portion of the insulation substrate is reduced. When a heating device is disposed on the patterned circuit layer, the heat generated by the heating device passes through the insulation substrate having a thinner thickness to be transmitted to an external environment. Therefore, the thermal resistance of the heat dissipation path is effectively reduced, and thereby thermal conduction effects of the substrate structure are enhanced.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided that they fall within the scope of the following claims and their equivalents.

What is claimed is:

1. A method of manufacturing a substrate structure, comprising:
providing an insulation substrate having an upper surface;
irradiating a portion of the upper surface of the insulation substrate with a first laser beam so as to form a first intaglio pattern, wherein the first laser beam is infrared (IR) laser beam or fiber laser beam, and the first intaglio pattern has a modification surface;
forming a first metal layer on the upper surface of the insulation substrate, wherein the first metal layer covers the upper surface of the insulation layer and the modification surface of the first intaglio pattern, and fills up the first intaglio pattern; and
performing a grinding process on the first metal layer so as to expose the upper surface of the insulation substrate and define a first patterned circuit layer, wherein a first upper surface of the first patterned circuit layer is coplanar with the upper surface of the insulation substrate.

2. The method of manufacturing the substrate structure as claimed in claim 1, wherein a material of the insulation substrate comprises ceramics or glass.

3. The method of manufacturing the substrate structure as claimed in claim 1, wherein a depth of the first intaglio pattern is from 0.3% to 60% of the thickness of the insulation substrate.

4. The method of manufacturing the substrate structure as claimed in claim 1, wherein the method of forming the first metal layer on the upper surface of the insulation substrate is an electroless plating process.

5. The method of manufacturing the substrate structure as claimed in claim 1, wherein a material of the first metal layer comprises copper or nickel.

6. The method of manufacturing the substrate structure as claimed in claim 1, further comprising:
forming a solder mask on the first patterned circuit layer after performing the grinding process on the first metal layer, wherein the solder mask exposes a portion of the first patterned circuit layer; and
forming a surface treatment layer on the first patterned circuit layer exposed by the solder mask.

7. The method of manufacturing the substrate structure as claimed in claim 1, wherein when the insulation substrate is provided, the insulation substrate already has a cavity, and the upper surface is a three-dimensional (3-D) surface.

8. The method of manufacturing the substrate structure as claimed in claim 1, wherein the insulation substrate further has a lower surface opposite to the upper surface, and the method of manufacturing the substrate structure further comprises:
irradiating a portion of the lower surface of the insulation substrate with a second laser beam before the first metal layer is formed on the upper surface of the insulation substrate, so as to form a second intaglio pattern.

9. The method of manufacturing the substrate structure as claimed in claim 8, further comprising:
forming a second metal layer on the lower surface of the insulation substrate after forming the second intaglio pattern, wherein the second metal layer fills up the second intaglio pattern and forms a second patterned circuit layer, and a second lower surface of the second patterned circuit layer is coplanar with the lower surface of the insulation substrate.

10. The method of manufacturing the substrate structure as claimed in claim 8, wherein a depth of the first intaglio pattern is from 0.3% to 40% of the thickness of the insulation substrate, and a depth of the second intaglio pattern is from 0.3% to 40% of the thickness of the insulation substrate.

11. A substrate structure manufactured by the method of manufacturing the substrate structure as claimed in claim 1, comprising:
an insulation substrate, having an upper surface and a first intaglio pattern situated on the upper surface; and
a first patterned circuit layer, disposed in the first intaglio pattern and filling up the first intaglio pattern, wherein a first surface of the first patterned circuit layer is coplanar with the upper surface of the insulation substrate.

12. The substrate structure as claimed in claim 11, wherein the insulation substrate further has a lower surface opposite to the upper surface and a second intaglio pattern situated on the lower surface.

13. The substrate structure as claimed in claim 12, further comprising:
a second patterned circuit layer, disposed in the second intaglio pattern and filling up the second intaglio pattern, wherein a second lower surface of the second patterned circuit layer is coplanar with the lower surface of the insulation substrate.

14. The substrate structure as claimed in claim 11, wherein the insulation substrate further has a cavity, and the upper surface is a 3-D surface.

15. The substrate structure as claimed in claim 11, further comprising:
a solder mask, disposed on the first patterned circuit layer, wherein the solder mask exposes a portion of the first patterned circuit layer; and
a surface treatment layer, disposed on the first patterned circuit layer exposed by the solder mask.
